(19) United States
(12) Patent Application Publication
(10) Pub. No.: US 2004/0166632 A1
(43) Pub. Date: Aug. 26, 2004

(54) METHOD OF FABRICATING FLASH MEMORY

(76) Inventors: PEI-REN JENG, HSINCHU (TW); TZUNG-TING HAN, I-LAN (TW); JUNG-YU HSIEH, HSINCHU CITY (TW); JUNE-MIN YAO, HSINCHU (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/248,831

(22) Filed: Feb. 24, 2003

(51) Int. Cl. H01L 21/336

(52) U.S. Cl. 438/261; 438/264

(57) ABSTRACT

A method of fabricating a flash memory. A tunneling dielectric layer and a conductive layer are formed on a substrate. The conductive layer is patterned to form a floating gate. A source/drain region is formed in the substrate between the floating gates. A gate dielectric layer is formed. The gate dielectric layer includes an oxide layer formed on the floating gate by in-situ steam generation (ISSG). A control gate is formed on the gate dielectric layer.

### BACKGROUND OF INVENTION

1. Field of the Invention

The invention relates in general to a method of fabricating a flash memory, and more particularly, to a method of fabricating a gate dielectric layer of a flash memory.

2. Related Art of the Invention

Flash memory has been broadly applied in personal computers and electronic products due to the superior data retention characteristics.

The typical flash memory has a stack-gate structure, which comprises a tunneling oxide layer, a polysilicon floating gate used to store charges, a silicon oxide/silicon nitride/silicon oxide (ONO) dielectric layer, and a polysilicon control gate used to control the data access.

In the conventional fabrication method of the flash memory, furnace thermal oxidation or high-temperature oxidation is used for forming the oxide layer of the gate dielectric layer. As the temperature of the above two processes is between 750° C. to about 950° C. and require an operation time of about 4 hours to about 6 hours, the thermal budget is significant high. As a result, the profiles of source and drain regions expand due to diffusion of the dopant therein. The distance between neighboring source and drain regions is decreased, that is, the channel length is shortened, to easily cause punch through. In addition, the surface of the oxide layer formed by the conventional furnace thermal oxidation is coarse and problematic in electric performance.

### SUMMARY OF INVENTION

The present invention provides a method of fabricating a flash memory including an oxide layer with smooth surface and good electric characteristics.

The present invention further provides a method fabricating a flash memory to avoid dopant of the source and drain regions from diffusing outwards, so as to prevent punch through under normal operation voltage.

The present invention provides a method of fabricating a flash memory. A tunneling dielectric layer is formed on a substrate, and a conductive layer is formed on the tunneling dielectric layer. The conductive layer is patterned to form a floating gate. A gate dielectric layer is formed. The gate dielectric layer includes an oxide layer formed on the floating gate by in-situ steam generation (ISSG). A control gate is formed on the gate dielectric layer.

In the above method, the oxide layer of the gate dielectric layer covering the control gate is formed by in-situ steam generation. As the in-situ steam generation uses a free radical reaction to form the oxide layer, the oxide layer is fabricated with a smooth surface and good electric characteristics. In addition, the operation temperature of the in-situ steam generation of about 850° C. to about 1000° C. lasts for only 2 to 3 minutes, that is, the thermal process time is short, so that the thermal budget is low. Therefore, the dopant in the source/drain region is prevented from diffusing outwardly, and the punch through effect under normal operation voltage is also avoided. As the time of thermal process for forming the oxide layer is reduced, and the overall process time is reduced.

### BRIEF DESCRIPTION OF DRAWINGS

These, as well as other features of the present invention, will become more apparent upon reference to the drawings wherein:

FIGS. 1A to 1E are cross sectional views showing a fabrication process of a flash memory according to one embodiment of the present invention; and

FIG. 2 shows the comparison of voltage-breakdown time of the devices fabricated by the present invention and prior art.

### DETAILED DESCRIPTION

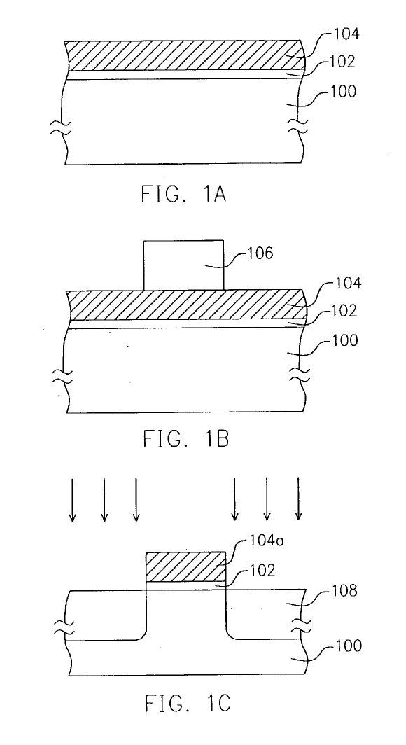

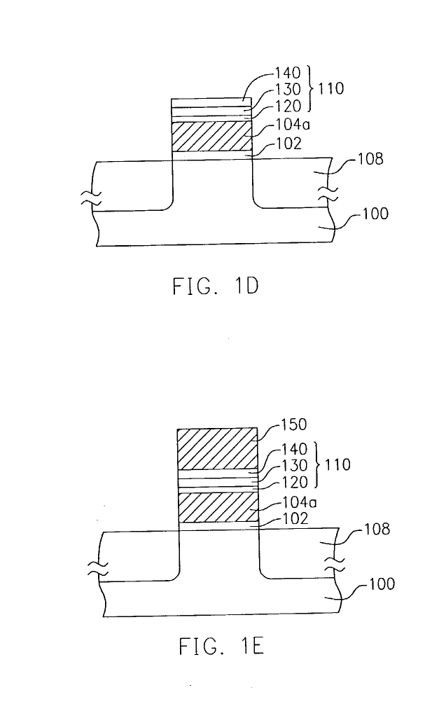

FIGS. 1A to 1E are cross sectional views showing a fabrication process of a flash memory according to one embodiment of the present invention.

Referring to FIG. 1A, a substrate 100 is provided. The substrate 100 includes silicon substrate, for example. A tunneling dielectric layer 102 and a conductive layer 104 are formed on the substrate 100. The material of the tunneling dielectric layer 102 includes silicon oxide formed by thermal oxidation, for example.

The material for forming the conductive layer 104 includes doped polysilicon formed by low-pressure chemical vapor deposition (LPCVD) using silane as a gas 0 source, followed an ion implantation step. The deposition temperature is about 575° C. to about 650° C., and the operation pressure is about 0.3 torr to about 0.6 torr.

Referring to FIG. 1B, a patterned photoresist layer 106 is formed on the conductive layer 104. The conductive layer 104 is etched using the photoresist layer 106 as a mask to form the patterned conductive layer 104a as shown in FIG. 1C.

Referring to FIG. 1C, the photoresist layer 106 is removed. Source/drain region 108 is formed in the substrate 100 at two sides of the patterned conductive layer 104a.

Referring to FIG. 1D, a gate dielectric layer 110 is formed on the patterned conductive layer 104a. The material for forming the gate dielectric layer 110 includes silicon oxide, silicon oxide/silicon nitride or silicon oxide/silicon nitride/silicon oxide (ONO). The good electric performance of the oxide layer in contact with the patterned conductive layer 104a is very demanding for a flash memory to avoid leakage current occurring to the floating gate used for charge storage and early electric breakdown. In the example of using silicon oxide/silicon nitride/silicon oxide for forming the gate dielectric layer 112, the present invention uses in-situ steam generation to form a uniform oxide layer 120 on the patterned conductive layer 104a, followed by sequentially forming a silicon nitride layer 130 and another silicon oxide layer 140 thereon by low-pressure chemical vapor deposition and a step of in-situ steam generation or low-pressure chemical vapor deposition, respectively.

In the above process, the machine for forming the in-situ steam generation includes a rapid thermal processing apparatus. The machine has a chamber surrounded by tungsten heating elements, such that the chip disposed in the chamber can be heated up to over 850° C. within 100 seconds. After the thermal process (that is, after about 60 seconds for the oxidation reaction), the temperature is dropped to the original temperature within 30 seconds. Therefore, compared to prior art that uses the furnace to perform the gate oxide layer, the thermal budget is greatly reduced, such that the problem of dopant diffusion of the source/drain regions 108 is resolved. Further, as the thermal process is complete in a very short period of time, and the process time is reduced. In addition, the reaction gases for the in-situ steam generation process include hydrogen and oxygen with a proportion of 1% to 33% and 99% to 67%, respectively. The operation temperature is about 850° C. to about 1000° C., and the operation pressure is about 5 torr to about 15 torr with an operation time between about 50 seconds to about 70 seconds. When the reaction gases (hydrogen and oxygen) are introduced into the chamber, the hydrogen and the oxygen are reacted under a heating environment to form water steam. The patterned conductive layer 104a is thus exposed in a water steam environment, and the oxygen free radical is reacted with the surface of the patterned conductive layer 104a to form the silicon oxide layer. The reaction mechanism of the reaction gases in the chamber includes:

1 H₂+O₂→H₂O (1)

2 H₂+OH→H₂O+H (2)

3 O₂+H→OH+O (3)

4 H₂+→OH+H (4)

5

As the oxygen free radical produced in the reaction formula (3) is uniformly in contact with the surface of the patterned conductive layer 104a, the surface of the oxide layer is smooth and the electric characteristics of the oxide layer are good.

Referring to FIG. 1E, another conductive layer 112 is formed on the gate dielectric layer 110 as a control gate. The material for forming the control gate includes doped polysilicon and metal silicide. The subsequent process is known to people of ordinary skill in the art and is not further described.

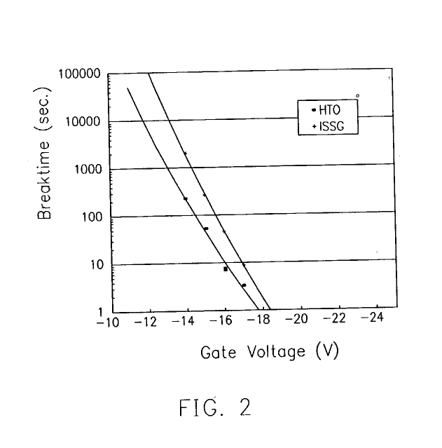

FIG. 2 shows the relationship between the voltage and the breakdown time of devices using in-situ steam generation to form the silicon oxide layer formed on the floating gate and using the conventional thermal oxidation to form the silicon oxide layer.

The experiment condition for forming the oxide layer using in-situ steam generation includes using hydrogen and oxygen as the reaction gases with flow rates of 6 l/min and 12 l/min, respectively. Thereby, the proportion of hydrogen in the chamber is about 33%, while the proportion of oxygen is about 67%. The reaction temperature is about 850° C., and the reaction time is about 2 minutes. For the conventional thermal oxidation, oxygen is used as the reaction gas. The reaction temperature is 750° C. for 40-50 minutes. After the device is fabricated, different voltages are applied to the gate for performing device electric breakdown test, and a voltage-breakdown time graph is shown in FIG. 2. As shown in FIG. 2, the silicon oxide fabricated by in-situ steam generation has a longer lifetime.

According to the above, the present invention uses in-situ steam generation to produce an oxide layer as the gate dielectric layer covering the floating gate that has a smooth surface and good electric performance since a free radical is used for reaction. In addition, the operation temperature of 850-1000° C. is maintained for about 2 to 3 minutes, such that the thermal budget is relatively low. Therefore, the dopant in the source/drain region is prevented from diffusing outwardly to avoid punch-through under normal operation voltage. On the other hand, as the time for forming the oxide layer by using rapid thermal process is very short, the process time is shortened, and the throughput is enhanced.

Other embodiments of the invention will appear to those skilled in the art from consideration of the specification and practice of the invention disclosed herein. It is intended that the specification and examples be considered as exemplary only, with a true scope and spirit of the invention being indicated by the following claims.

1. A method of fabricating a flash memory, comprising:
forming a tunneling dielectric layer on a substrate;
forming a conductive layer on the tunneling dielectric layer;
patterning the conductive layer into a floating gate;
forming a source/drain region in the substrate at respective sides of the floating gate;
forming a gate dielectric layer on the floating gate, the gate dielectric layer including a first silicon oxide layer formed by in-situ steam generation; and
forming a control gate on the gate dielectric layer.

2. The method according to claim 1, further comprising forming a silicon nitride layer on the first silicon oxide layer.

3. The method according to claim 2, further comprising forming a second silicon oxide layer on the silicon nitride layer.

4. The method according to claim 1, wherein the step of forming the conductive layer further comprises forming a doped polysilicon layer.

5. The method according to claim 1, further comprising using hydrogen and oxygen as reaction gases for the in-situ steam generation.

6. The method according to claim 5, wherein the hydrogen has a proportion of about 1% to about 33%, and the oxygen has a proportion of about 99% to about 67%.

7. The method according to claim 1, wherein the in-situ steam generation is performed at about 850° C. to about 1000° C. under a pressure of about 5 torr to about 15 torr.

8. The method according to claim 1, wherein the in-situ steam generation is performed with a period of oxidation by 50 70 seconds.

9. A method of fabricating a flash memory, comprising:
forming a tunneling dielectric layer on a substrate;
forming a conductive layer on the tunneling dielectric layer;
patterning the conductive layer into a floating gate;
forming a source/drain region in the substrate at respective sides of the floating gate;
performing an oxygen free radical reaction to form a bottom oxide layer on the floating gate;
forming a silicon nitride layer on the bottom oxide layer;
forming a top oxide layer on the silicon nitride layer; and
forming a control gate on the top silicon oxide layer.

10. The method according to claim 9, further comprising forming a doped polysilicon layer as the conductive layer.

11. The method according to claim 9, wherein the oxygen free radical reaction is an in-situ steam generation process.

12. The method according to claim 11, further comprising using hydrogen and oxygen as reaction gases for the in-situ steam generation.

13. The method according to claim 12, wherein the hydrogen has a proportion of about 1% to about 33%, and the oxygen has a proportion of about 99% to about 67%.

14. The method according to claim 11, wherein the in-situ steam generation is performed at about 850° C. to about 1000° C. under a pressure of about 5 torr to about 15 torr.

15. The method according to claim 11, wherein an oxidation reaction time of the in-situ steam generation process is about 50 second to about 70 second.

16. A method of fabricating a gate dielectric layer, comprising using an oxygen free radical reaction process to form an oxide layer on a polysilicon layer.

17. The method according to claim 16, wherein the oxygen free radical reaction is an in-situ steam generation process.

18. The method according to claim 17, further comprising using hydrogen and oxygen as reaction gases for the in-situ steam generation.

19. The method according to claim 18, wherein the hydrogen has a proportion of about 1% to about 33%, and the oxygen has a proportion of about 99% to about 67%.

20. The method according to claim 17, further comprising forming a silicon nitride layer on the oxide layer, and another oxide layer on the silicon nitride layer.
